(19) United States
(12) Patent Application Publication
(10) Pub. No.: US 2026/0033182 A1
(43) Pub. Date: Jan. 29, 2026

(54) DISPLAY MODULE, METHOD FOR MANUFACTURING DISPLAY DEVICE USING THE SAME, AND ELECTRONIC DEVICE

(71) Applicant: SAMSUNG DISPLAY CO., LTD., YONGIN-SI (KR)

(72) Inventors: WONJONG OHN, Yongin-si (KR); MOON-CHUL PARK, Yongin-si (KR); YU-HAN BAE, Yongin-si (KR); SOO-HYUN LEE, Yongin-si (KR)

(21) Appl. No.: 19/095,146

(22) Filed: Mar. 31, 2025

(30) Foreign Application Priority Data
Jul. 25, 2024 (KR) 10-2024-0098770

(51) Int. Cl. H10K 59/131; H10K 59/12

(52) U.S. Cl. CPC H10K 59/131; H10K 59/1201

(57) ABSTRACT

A display module includes: a display panel including a plurality of pixels located in a display area, a plurality of first test pads located in a first pad area, a plurality of second-first test pads located in a second pad area spaced apart from the first pad area and electrically connected to the first test pads, and a plurality of second-second test pads located in the second pad area; a driving integrated circuit bonded to the first test pads, the driving integrated circuit configured to provide driving signals to the pixels; a first circuit board bonded to the second-first test pads and the second-second test pads; and a second circuit board bonded to one end of the first circuit board, the second circuit board including a first test terminal group electrically connected to the second-first test pads and a second test terminal group electrically connected to the second-second test pads.

### CROSS-REFERENCE TO RELATED APPLICATION

This application claims priority under 35 U.S.C. § 119 to Korean Patent Application No. 10-2024-0098770 filed on Jul. 25, 2024 in the Korean Intellectual Property Office (KIPO), the disclosure of which is incorporated by reference herein in its entirety.

### BACKGROUND

### 1. Technical Field

The present disclosure relates to a display device. More particularly, one or more embodiments relate to a display module, a method for manufacturing the same, and an electronic device.

### 2. Description of the Related Art

As information technology develops, the importance of display devices is being highlighted. Display devices can act as a communication interface between user(s) and information. Accordingly, the use of display devices such as a liquid crystal display device, an organic light emitting display device, a plasma display device, and the like is increasing.

Meanwhile, a display device may include a display panel including a plurality of pixels, a driver which may provide signals to the plurality of pixels, and a circuit board which receives external signals. The display panel may include a plurality of gate lines and a plurality of data lines, and each pixel may be connected to the gate line and the data line to receive a predetermined signal. The driver may include a gate driver and a data driver. The gate line may receive a gate signal from the gate driver, and the data line may receive a data signal from the data driver.

The driver may be configured as a driving integrated circuit (driving IC). The driver may be bonded to the display panel. Likewise, the circuit board may be bonded to the display panel. At the time of bonding, if the bonding between the display panel and the driver, and the bonding between the display panel and the circuit board are not proper, the contact resistance may be high, which may have a negative effect on the operations of the display device. Thus, it may be advisable to measure the contact resistance of the bonded driver and the contact resistance of the bonded circuit board to ensure that the display device is driven properly.

### SUMMARY

One or more embodiments provide a display module for measuring a contact resistance between a display panel and a driving integrated circuit, and a contact resistance between the display panel and a main circuit board.

One or more embodiments provide a method for manufacturing a display device using the display module.

One or more embodiments provide an electronic device with a display module.

However, the embodiments of the present disclosure are not limited to those described herein. Additional features of the present disclosure will become apparent to those of ordinary skill in the art upon reviewing the detailed description below.

According to an embodiment of the present disclosure, there is provided a display module comprising: a display panel comprising: a plurality of pixels located in a display area, a plurality of first test pads located in a first pad area, a plurality of second-first test pads located in a second pad area spaced apart from the first pad area and electrically connected to the first test pads, and a plurality of second-second test pads located in the second pad area; a driving integrated circuit bonded to the first test pads, the driving integrated circuit configured to provide driving signals to the pixels; a first circuit board bonded to the second-first test pads and the second-second test pads; and a second circuit board bonded to one end of the first circuit board, the second circuit board including a first test terminal group electrically connected to the second-first test pads and a second test terminal group electrically connected to the second-second test pads.

In an embodiment, the first test terminal group may include first-first, first-second, first-third, and first-fourth test terminals and the second test terminal group may include second-first, second-second, second-third, and second-fourth test terminals, wherein the first-first and second-first test terminals may be configured receive a current flow, the first-second and second-second test terminals may be configured to receive a ground voltage, the first-third and second-third test terminals may be configured to receive a first voltage, and the first-fourth and the second-fourth test terminals may be configured to receive a second voltage different from the first voltage.

In an embodiment, the second circuit board may comprise a first-first test connection line electrically connected to the first-first test terminal and to one of the second-first test pads; a first-second test connection line electrically connected to the first-second test terminal and to another one of the second-first test pads; a first-third test connection line electrically connected to the first-third test terminal and to another one of the second-first test pads; and a first-fourth test connection line electrically connected to the first-fourth test terminal and to remaining one of the second-first test pads.

In an embodiment, the second circuit may further comprise: a second-first test connection line electrically connected to the second-first test terminal and to one of the second-second test pads; a second-second test connection line electrically connected to the second-second test terminal and to another one of the second-second test pads; a second-third test connection line electrically connected to the second-third test terminal and to another one of the second-second test pads; and a second-fourth test connection line electrically connected to the second-fourth test terminal and to remaining one of the second-second test pads.

In an embodiment, a display module is provided wherein a first connector is disposed on the first circuit board, a second connector is disposed on the second circuit board, and the first circuit board and the second circuit board are bonded through the first connector and the second connector.

In an embodiment, the display panel may further comprise first, second, third, and fourth test lines each, respectively, electrically connected to one of the first test pads and one of the second-first test pads, and the first circuit board includes: first-first, first-second, first-third, and first-fourth test transmission lines each, respectively, electrically connected to one of the second-first test pads and to the first and second connectors; and second-first, second-second, second-third, and second-fourth test transmission lines each, respectively, electrically connected to one of the second-second test pads and to the first and second connectors.

In an embodiment, the first, second, third, and fourth test lines may be connected one-to-one to the second-first test pads, and the second and third test lines may be connected to a single first test pad among the first test pads.

In an embodiment, the first-first, first-second, first-third, and first-fourth test transmission lines may be connected one-to-one to the second-first test pads, and the second-second and second-third test transmission lines may be connected to a single second-second test pad among the second-second test pads.

In an embodiment, the driving integrated circuit may comprise a switching circuit electrically connected to at least some of the first test pads, the switching circuit including a switching element configured to selectively receive a ground voltage.

In an embodiment, the display panel may further comprise a plurality of input pads located at a first end of the first pad area; and a plurality of output pads located at a second end of the first pad area opposite to the first end, the output pads configured to output the driving signals to the pixels. And, the first test pads may be located at the second end of the first pad area.

In an embodiment, the driving integrated circuit may comprise a plurality of input bumps connected one-to-one to the input pads; a plurality of test bumps connected one-to-one to the first test pads; and a plurality of output bumps connected one-to-one to the output pads.

In an embodiment, the first circuit board may comprise a plurality of second-first test bumps connected one-to-one to the second-first test pads; and a plurality of second-second test bumps connected one-to-one to the second-second test pads.

A method for manufacturing a display device according to embodiments of the present disclosure, the method comprising: forming a plurality of pixels in a display area of a display panel; forming a plurality of first test pads in a first pad area of the display panel; forming a plurality of second-first test pads in a second pad area of the display panel spaced apart from the first pad area; connecting electrically the first test pads to the second-first test pads; and forming a plurality of second-second test pads in the second pad area of the display panel; bonding a driving integrated to the first test pads, the driving integrating circuit providing driving signals to the pixels; bonding a first circuit board to the second-first test pads and the second-second test pads; and bonding a second circuit board to one end of the first circuit board and disposing a first test terminal group and a second terminal group on the second circuit board, the first test terminal group connecting electrically to the second-first test pads and the second test terminal group connecting electrically to the second-second test pads; and removing the second circuit board from the first circuit board.

In an embodiment, the first test terminal group includes first-first, first-second, first-third, and first-fourth test terminals and the second test terminal group includes second-first, second-second, second-third, and second-fourth test terminals. The method may include before the removing the second circuit board, applying a current to the first-first and second-first test terminals, applying a ground voltage to the first-second and second-second test terminals, applying a first voltage to the first-third and second-third test terminals, and applying a second voltage different from the first voltage to the first-fourth and the second-fourth test terminals.

In an embodiment, the bonding the second circuit board comprises: connecting electrically the first-first test terminal to one of the second-first test pads through a first-first test connection line; connecting electrically the first-second test terminal and another one of the second-first test pads through a first-second test connection line; connecting electrically the first-third test terminal and another one of the second-first test pads through a first-third test connection line; and connecting electrically the first-fourth test terminal and remaining one of the second-first test pads through a first-fourth test connection line.

In an embodiment, the bonding the second circuit board further comprises: connecting electrically the second-first test terminal and one of the second-second test pads through a second-first test connection line; connecting electrically the second-second test terminal and another one of the second-second test pads through a second-second test connection line; connecting electrically the second-third test terminal and another one of the second-second test pads through a second-third test connection line; and connecting electrically the second-fourth test terminal and remaining one of the second-second test pads through a second-fourth test connection line.

In an embodiment, the method further includes the steps of: disposing a first connector on the first circuit board, disposing a second connector on the second circuit board, and bonding the first circuit board and the second circuit board through the first connector and the second connector, connecting electrically one of the first test pads to one of the second-first test pads through first, second, third, and fourth test lines, respectively, and bonding the first circuit board comprising: connecting electrically one of the second-first test pads to the first and second connectors through first-first, first-second, first-third, and first-fourth test transmission lines, respectively; and connecting electrically one of the second-second test pads to the first and second connectors through second-first, second-second, second-third, and second-fourth test transmission lines, respectively.

In an embodiment, the method further includes the steps of: connecting the first, second, third, and fourth test lines one-to-one to the second-first test pads, connecting the second and third test lines to a single first test pad among the first test pads, connecting the first-first, first-second, first-third, and first-fourth test transmission lines one-to-one to the second-first test pads, and connecting the second-second and second-third test transmission lines to a single second-second test pad among the second-second test pads.

In an embodiment, the method includes connecting electrically a switching circuit to at least some of the first test pads, and configuring a switching element of a switching circuit to selectively receive a ground voltage.

In an embodiment, the manufacturing the display module may include forming the display panel, bonding the driving integrated circuit to the first test pads, bonding the first circuit board to which the second circuit board is attached to the second-first test pads and the second-second test pads, and connecting the second circuit board to an inspection device to inspect the first circuit board.

In a display module according to embodiments of the present disclosure, a second circuit board bonded to a first circuit board may include a first test terminal group and a second test terminal group to measure a contact resistance between a display panel and a driving integrated circuit, and a contact resistance between the display panel and the first circuit board.

After inspecting the first circuit board for defects, the second circuit board may be removed from the first circuit board. Accordingly, an area of the first circuit board may be reduced and the degree of design freedom may be increased.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to embodiments of the present disclosure.

FIG. 2 is a cross-sectional view schematically illustrating the display device of FIG. 1.

FIG. 3 is a view showing a bent shape of the display device of FIG. 1.

FIG. 4 is a block diagram illustrating an external device electrically connected to the display device of FIG. 1.

FIG. 5 is an enlarged cross-sectional view of area A of FIG. 2.

FIG. 6 is an enlarged plan view of a sub-area of FIG. 1.

FIG. 7 is a plan view showing a display module according to embodiments of the present disclosure.

FIG. 8 is a cross-sectional view illustrating a bonding of a first circuit board and a second circuit board of FIG. 7.

FIG. 9 is a plan view showing a second circuit board included in the display module of FIG. 7.

FIG. 10 is a plan view showing a driving integrated circuit included in the display module of FIG. 7.

FIGS. 11, 12, and 13 are plan views for explaining a method for manufacturing a display device using a display module according to embodiments of the present disclosure.

FIG. 14 is a block diagram showing an electronic device according to embodiments of the present disclosure.

FIG. 15 are schematic diagrams showing examples electronic devices according to various embodiments.

### DETAILED DESCRIPTION OF THE EMBODIMENTS

Hereinafter, a display module and a method for manufacturing a display device using the display module according to embodiments of the present disclosure, and an electronic device with a display module will be explained in detail with reference to the accompanying drawings. The same reference numerals are used for the same components in the drawings, and redundant descriptions of the same components will be omitted.

The present disclosure focuses on ensuring proper bonding between a display panel and a driver, and between a display panel and a first (main) circuit board of a display device/module, while at the same time, reducing the area of the first (main) circuit board and increasing the design freedom. Proper bonding between a display panel and a driver may be ensured by evaluating contact resistance between the display panel and the driver. Likewise, proper bonding between a display panel and a first (main) circuit board may be ensured by evaluating a contact resistance between the display panel and the first circuit board. High contact resistance may have a negative effect on the performance of a display device/module, which includes the display panel.

In traditional designs, in order to measure contact resistance between a display panel and a driver, and between a display panel and a first (main) circuit board, a first terminal group and a second terminal group may be disposed on the first (main) circuit board. The area covered by the first and second terminal groups may be large, which may reduce the design freedom of the display device/module.

To resolve these challenges, a second circuit board may be bonded to the first circuit board. The second circuit board bonded to the first circuit board may include the first test terminal group and the second test terminal group to measure the contact resistance between the display panel and the driver, and the contact resistance between the display panel and the first circuit board. After measuring the contact resistance(s), the second circuit board may be removed from the first circuit board. Accordingly, the area of the first circuit board may be reduced, increasing the design freedom.

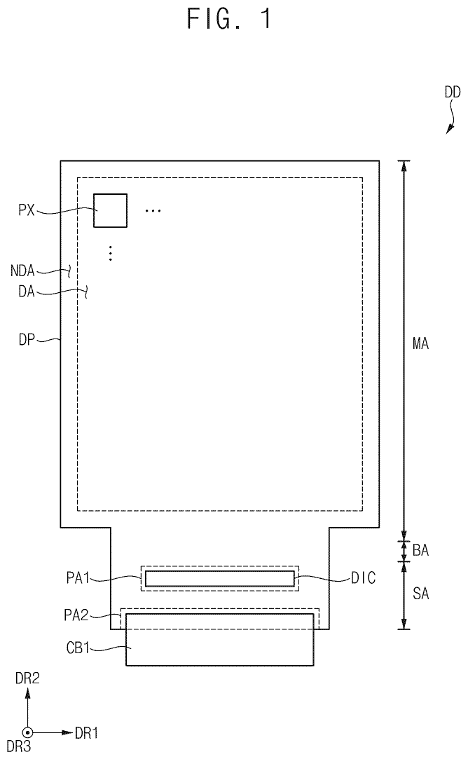

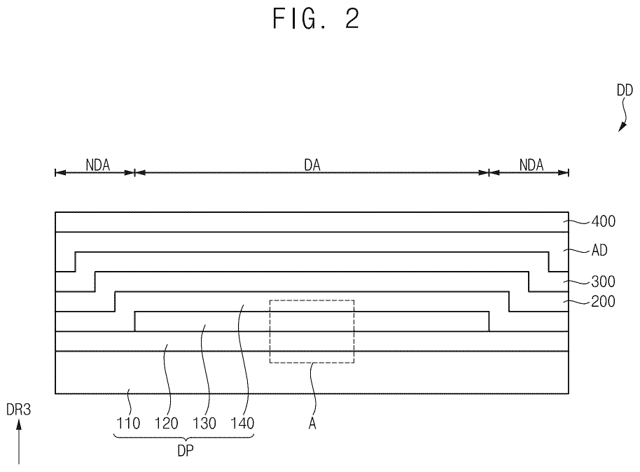

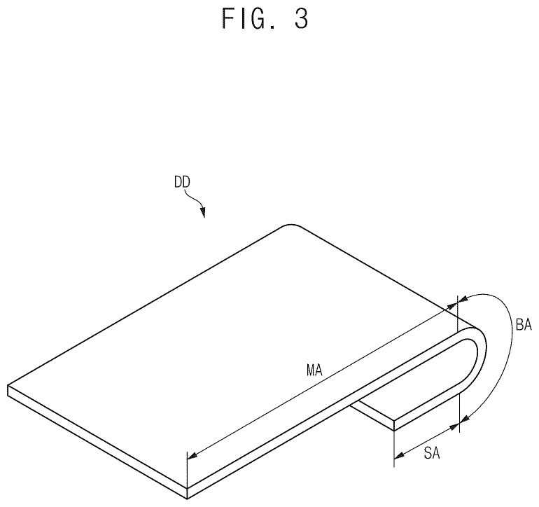

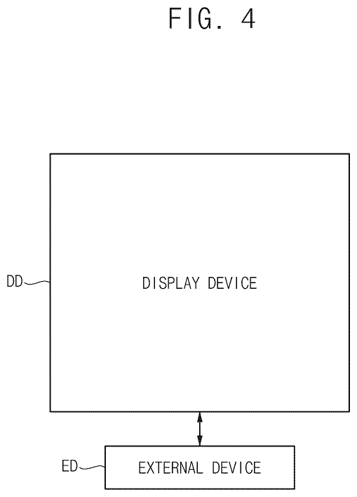

FIG. 1 is a plan view showing a display device according to embodiments of the present disclosure. FIG. 2 is a cross-sectional view schematically illustrating the display device of FIG. 1. FIG. 3 is a view showing a bent shape of the display device of FIG. 1. FIG. 4 is a block diagram illustrating an external device electrically connected to the display device of FIG. 1.

Referring to FIGS. 1, 3, and 4, the display device DD according to embodiments of the present disclosure may include a display panel DP, a driving integrated circuit DIC, and a first circuit board CB1.

The display device DD may have a rectangular planar shape (e.g., a rectangular planar shape with rounded corners). However, embodiments of the present disclosure are not necessarily limited thereto, and the display device DD may have various planar shapes.

The display panel DP may include a display area DA and a non-display area NDA. The display area DA may be an area that can display an image by generating light or adjusting the transmittance of light provided from an external light source. The non-display area NDA may be an area that does not display images. The non-display area NDA may be located around the display area DA. For example, the non-display area NDA may entirely surround the display area DA.

The display panel DP may include a plurality of pixels PX arranged in the display area DA. The pixels PX may be arranged in a matrix form along a first direction DR1 and a second direction DR2 intersecting the first direction DR1. However, embodiments of the present invention are not necessarily limited thereto, and the pixels PX may be arranged in various forms.

Each of the pixels PX may include a driving element (e.g., a driving thin film transistor) which generates a driving current, and a light-emitting element (e.g., an organic light emitting diode) electrically connected to the driving element and which generates light based on the driving current. Accordingly, each of the pixels PX may emit light according to the driving current. As the pixels PX emit light, the display area DA may display an image.

Lines connected to the pixels PX may be further disposed (or located) in the display area DA. For example, the lines may include data lines, gate signal lines, power lines, and the like.

A driver for driving the pixels PX may be disposed (or located) in the non-display area NDA. For example, the driver may include a gate driver, a light-emitting driver, a power supply voltage generator, a timing controller, and the like. The pixels PX may emit light based on signals received from the driver.

The non-display area NDA may include a bending area BA and a sub-area SA. The sub-area SA may be located on one side of the display area DA. In an embodiment, the sub-area SA may be located spaced apart from one side of the display area DA in a direction opposite to the second direction DR2.

The sub-area SA may include a first pad area PA1 and a second pad area PA2 spaced apart from each other. The first pad area PA1 may be located between the bending area BA and the second pad area PA2 in a plan view. The second pad area PA2 may be located at an end of the sub-area SA.

The bending area BA may be located between the display area DA and the sub-area SA on a plane. As shown in FIG. 3, the bending area BA may be bent based on a bending axis extending in the first direction DR1. In an embodiment, the sub-area SA may overlap a main area MA, which is defined as the display area DA and a portion of the non-display area NDA, in the plan view. For example, when the bending area BA is bent, the sub-area SA may be located under the main area MA. The display device DD may be provided in a shape in which the bending area BA is bent based on the bending axis.

The driving integrated circuit DIC may be bonded to the first pad area PA1 on the display panel DP. The driving integrated circuit DIC may convert a digital data signal among the driving signals into an analog data signal and provide the converted data signal(s) to the pixels PX. In some embodiments, the driving integrated circuit DIC may be a data driver. A detailed description of how the display panel DP and the driving integrated circuit DIC are bonded in the first pad area PA1 will be described later.

The first circuit board CB1 may be bonded to the second pad area PA2 on the display panel DP. In an embodiment, one end of the first circuit board CB1 may be bonded to the second pad area PA2. The other end of the first circuit board CB1 may be electrically connected to an external device ED. Signals, voltages, and the like generated from the external device ED may be provided to the driving integrated circuit DIC and the pixels PX through the first circuit board CB1. The first circuit board CB1 may be referred to as a main circuit board.

In some embodiments, the first circuit board CB1 may be a flexible printed circuit board (FPCB), a printed circuit board (PCB), or a flexible flat cable (FFC). A detailed description of how the display panel DP and the first circuit board CB1 are bonded in the second pad area PA2 will be described later.

As shown in FIG. 4, the external device ED may be electrically connected to the display device DD. For example, the external device ED may be electrically connected to the display device DD through the first circuit board CB1. The external device ED may generate signals, voltages, and the like to display an image on the display device DD.

In FIG. 1, the driving integrated circuit DIC is shown as being disposed in a chip on plastic (COP) method or a chip on glass (COG) method, but embodiments of the present disclosure are not necessarily limited thereto. For example, the driving integrated circuit DIC may be disposed in a chip on film (COF) method.

Hereinafter, a stacked structure of the display device DD will be described with reference to FIG. 2.

Referring to FIG. 2, the display device DD may further include a touch sensor layer 200, an anti-reflection layer 300, an adhesive layer AD, and a window member 400.

The display panel DP may include a substrate 110, a pixel circuit layer 120 disposed on the substrate 110, a light-emitting element layer 130 disposed on the pixel circuit layer 120, and an encapsulation layer 140 disposed on the light-emitting element layer 130.

In some embodiments, substrate 110 may be a glass substrate, a metal substrate, or a polymer substrate. In an embodiment, the substrate 110 may be a flexible polymer substrate. However, embodiments of the present disclosure are not necessarily limited thereto, and the substrate 110 may be an inorganic layer, an organic layer, or a composite material layer.

In some embodiments, the pixel circuit layer 120 may include an insulating layer, a semiconductor element (e.g., transistor), a conductive layer, a signal line, and the like. The light-emitting element layer 130 may include a light-emitting element which generates light. For example, the light-emitting element may include an organic light-emitting material, an inorganic light-emitting material, an organic-inorganic light emitting material, a quantum dot, a micro LED, or a nano LED.

The encapsulation layer 140 may protect the light-emitting element layer 130 from foreign substances such as moisture and oxygen. For example, the encapsulation layer 140 may include at least one inorganic layer and at least one organic layer. In an embodiment, the encapsulation layer 140 may have a stacked structure of a first inorganic layer, an organic layer, and a second inorganic layer.

The touch sensor layer 200 may be disposed on the display panel DP. The touch sensor layer 200 may detect an external input applied from outside. The external input may be a user's input. For example, the user's input may include various types of external pressure, such as a part of the user's body, light, heat, pen, pressure, and the like. For example, the touch sensor layer 200 may be formed directly on the display panel DP through a continuous process. Alternatively, the touch sensor layer 200 may be manufactured in a separate process and then attached to the display panel DP. Alternatively, the touch sensor layer 200 may be omitted.

The anti-reflection layer 300 may be disposed (or located) on the touch sensor layer 200. The anti-reflection layer 300 may reduce the reflectance of external light incident from the outside of the display device DD. The anti-reflection layer 300 may be formed on the touch sensor layer 200 through a continuous process. For example, the anti-reflection layer 300 may include color filters which selectively transmit light of a specific color and a black matrix disposed (or located) between the color filters. Alternatively, the anti-reflection layer 300 may be omitted, and a polarizer may be disposed on the touch sensor layer 200.

The window member 400 may be attached to the anti-reflection layer 300 through the adhesive layer AD. The window member 400 may include a base film. In some embodiments, the base film may be a glass film or a synthetic resin film. The window member 400 may further include an anti-reflection layer or an anti-fingerprint layer.

In the embodiments described herein, a plane may be defined as the first direction DR1 and the second direction DR2 intersecting the first direction DR1. In an embodiment, the first direction DR1 and the second direction DR2 may be perpendicular to each other. In addition, a third direction DR3 may be perpendicular to the plane.

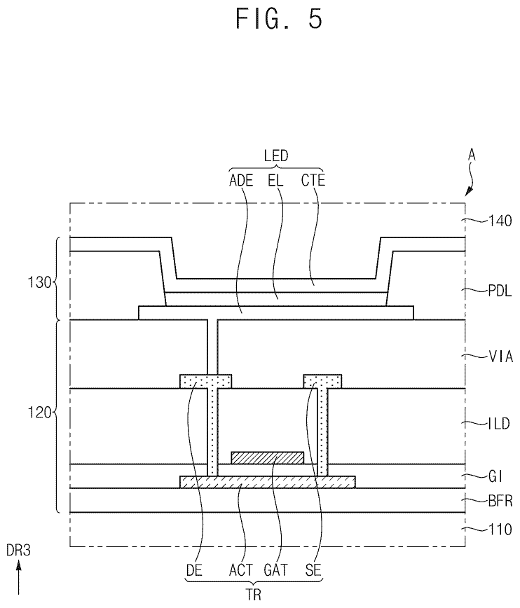

FIG. 5 is an enlarged cross-sectional view of area A of FIG. 2. For example, FIG. 5 is an enlarged cross-sectional view of each pixel PX of the display panel DP of FIGS. 1 and 2.

Referring to FIG. 5, as described above, the display panel DP may include the substrate 110, the pixel circuit layer 120, the light-emitting element layer 130, and the encapsulation layer 140. The pixel circuit layer 120 may include a buffer layer BFR, a gate insulating layer GI, a transistor TR, an interlayer insulating layer ILD, and a via insulating layer VIA. In addition, the light-emitting element layer 130 may include a pixel-defining layer PDL and a light-emitting element LED. In some embodiments, the transistor TR may include an active pattern ACT, a gate electrode GAT, a source electrode SE, and a drain electrode DE, and the light-emitting element LED may include an anode electrode ADE, a light-emitting layer EL, and a cathode electrode CTE.

The buffer layer BFR may be disposed (or located) on the substrate 110. The buffer layer BFR may prevent metal atoms or impurities from diffusing from the substrate 110 to the transistor TR. In addition, the buffer layer BFR may improve the flatness of the surface of the substrate SUB when the surface of the substrate 110 is not uniform. In some embodiments, the buffer layer BFR may include an inorganic material such as silicon oxide (SiOₓ), silicon nitride (SiNₓ), silicon oxynitride (SiOₓN_{y}), and the like. The materials disclosed herein may be used alone or in combination with each other.

The active pattern ACT may be disposed (or located) on the buffer layer BFR. The active pattern ACT may include a metal oxide semiconductor, an inorganic semiconductor (e.g., amorphous silicon, polysilicon, and the like), or an organic semiconductor. The active pattern ACT may include a source region, a drain region, and a channel region located between the source region and the drain region.

The metal oxide semiconductor may include a binary compound (ABₓ), a ternary compound (ABₓC_{y}), a quaternary compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. In some embodiments, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. The compounds disclosed herein may be used alone or in combination with each other.

The gate insulating layer GI may be disposed (or located) on the buffer layer BFR. The gate insulating layer GI may sufficiently cover the active pattern ACT and may have a substantially flat upper surface without creating a step around the active pattern ACT. Alternatively, the gate insulating layer GI may cover the active pattern ACT and may be disposed along a profile of the active pattern ACT with a uniform thickness. In some embodiments, the gate insulating layer GI may include an inorganic material such as silicon oxide (SiOx), silicon nitride (SiNx), silicon carbide (SiCx), silicon oxynitride (SiOxNy), silicon oxycarbide (SiOxCy), and the like. The compounds disclosed herein may be used alone or in combination with each other.

The gate electrode GAT may be disposed (or located) on the gate insulating layer GI. The gate electrode GAT may overlap the channel area of the active pattern ACT. The gate electrode GAT may include metal, alloy, metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNₓ), and the like. The examples disclosed herein may be used alone or in combination with each other.

The interlayer insulating layer ILD may be disposed (or located) on the gate insulating layer GI. The interlayer insulating layer ILD may sufficiently cover the gate electrode GAT and may have a substantially flat upper surface without creating a step around the gate electrode GAT. Alternatively, the interlayer insulating layer ILD may cover the gate electrode GAT and may be disposed along a profile of the gate electrode GAT with a uniform thickness. In some embodiments, the interlayer insulating layer ILD may include an inorganic material such as silicon oxide, silicon nitride, silicon carbide, silicon oxynitride, silicon oxycarbide, and the like, which may be used alone or in combination with each other.

The source electrode SE and the drain electrode DE may be disposed (or located) on the interlayer insulating layer ILD. The source electrode SE may be connected to the source region of the active pattern ACT through a contact hole penetrating a first portion of the gate insulating layer GI and the interlayer insulating layer ILD, and the drain electrode DE may be connected to the drain region of the active pattern ACT through a contact hole penetrating a second portion of the gate insulating layer GI and the interlayer insulating layer ILD. In some embodiments, each of the source electrode SE and the drain electrode DE may include a metal, alloy, metal nitride, conductive metal oxide, transparent conductive material, and the like, which may be used alone or in combination with each other.

Accordingly, the transistor TR including the active pattern ACT, the gate electrode GAT, the source electrode SE, and the drain electrode DE may be disposed (or located) in a display area (e.g., the display area DA of FIGS. 1 and 2) on the substrate 110.

The via insulating layer VIA may be disposed (or located) on the interlayer insulating layer ILD. The via insulating layer VIA may sufficiently cover the source electrode SE and the drain electrode DE. The via insulating layer VIA may include an inorganic material or an organic material. In some embodiments, the via insulating layer VIA may include an organic material such as phenolic resin, polyacrylates resin, polyimides resin, polyamides resin, siloxane resin, epoxy resin, and the like, which may be used alone or in combination with each other.

The anode electrode ADE may be disposed (or located) on the via insulating layer VIA. The anode electrode ADE may be connected to the drain electrode DE (or the source electrode SE) through a contact hole penetrating the via insulating layer VIA. In some embodiments, the anode electrode ADE may include metal, alloy, metal nitride, conductive metal oxide, transparent conductive material, and the like, which may be used alone or in combination with each other. In an embodiment, the anode electrode ADE may have a layered structure including ITO/Ag/ITO. However, embodiments of the present disclosure are not necessarily limited thereto.

The pixel defining layer PDL may be disposed (or located) on the via insulating layer VIA. The pixel defining layer PDL may cover an edge of the anode electrode ADE. In addition, an opening exposing at least a portion of an upper surface of the anode electrode ADE may be defined in the pixel defining layer PDL. For example, the pixel defining layer PDL may include an inorganic material or an organic material. In some embodiments, the pixel defining layer PDL may include an organic material such as epoxy resin, siloxane resin, and the like, which may be used alone or in combination with each other. In other embodiments, the pixel defining layer PDL may include an inorganic material and/or an organic material containing a light-blocking material such as black pigment, black dye, and the like.

The light-emitting layer EL may be disposed (or located) on the anode electrode ADE. In an embodiment, the light-emitting layer EL may be disposed (or located) in the opening of the pixel defining layer PDL. The light-emitting layer EL may include a light emitting material which emits light of a preset color. For example, the light-emitting layer EL may include a light emitting material which emits red light, green light, or blue light.

The cathode electrode CTE may be disposed (or located) on the pixel defining layer PDL and the light-emitting layer EL. In some embodiments, the cathode electrode CTE may include metal, alloy, metal nitride, conductive metal oxide, transparent conductive material, and the like, which may be used alone or in combination with each other.

Accordingly, the light-emitting element LED including the anode electrode ADE, the light-emitting layer EL, and the cathode electrode CTE may be disposed (or located) in the display area on the substrate 110. The light-emitting element LED may be electrically connected to the transistor TR. Accordingly, the light-emitting element LED may receive a driving signal from the transistor TR and generate light based on the driving signal.

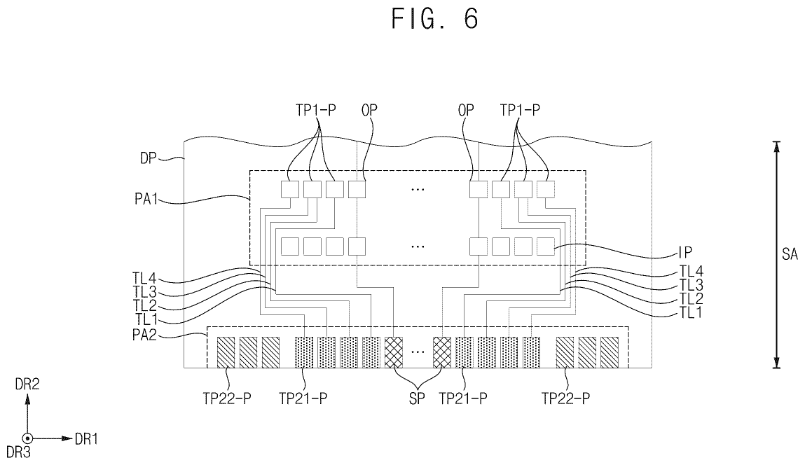

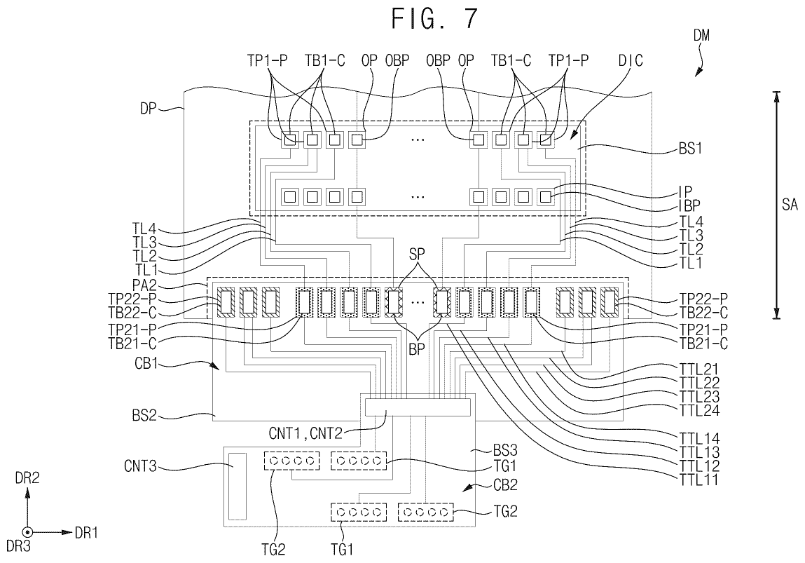

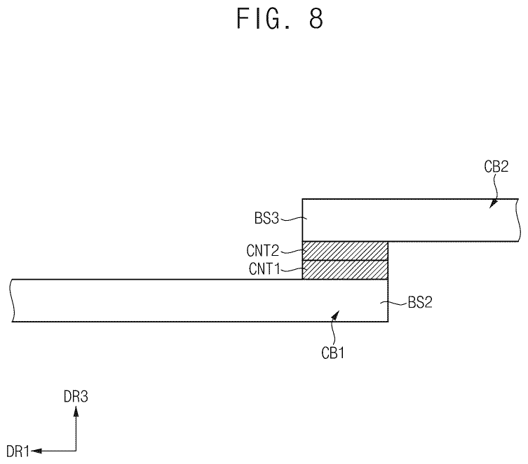

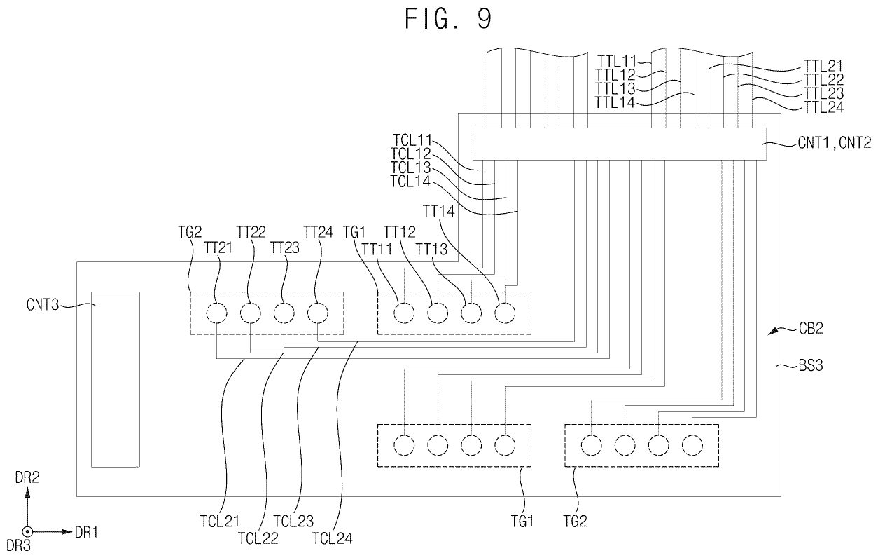

FIG. 6 is an enlarged plan view of a sub-area of FIG. 1. FIG. 7 is a plan view showing a display module according to embodiments of the present disclosure. FIG. 8 is a cross-sectional view illustrating a bonding of a first circuit board and a second circuit board of FIG. 7. FIG. 9 is a plan view showing a second circuit board included in the display module of FIG. 7.

FIG. 6 may show the display device DD before the driving integrated circuit DIC and the first circuit board CB1 are bonded to the sub-area SA of FIG. 1.

In an embodiment, the display module DM may include a display panel DP. The display panel may comprise a driving integrated circuit DIC and a first circuit board CB1 both bonded to the display panel DP. A second circuit board CB2 may be bonded to the first circuit board CB1, as shown in FIG. 7.

In an embodiment, the display module DM may include the display panel DP, the driving integrated circuit DIC, the first circuit board CB1, and the second circuit board CB2. An inspection to detect defects in the first circuit board CB1 may be performed using the display module DM. The second circuit board CB2 may be removed from the first circuit board CB1 after the inspection.

The display panel DP may further include a plurality of first test pads TP1-P, a plurality of output pads OP, a plurality of input pads IP, a plurality of second-first test pads TP21-P, a plurality of second-second test pads TP22-P, and a plurality of signal pads SP disposed (or located) in the sub-area SA.

The input pads IP may be disposed (or located) in the first pad area PA1. In an embodiment, the input pads IP may be disposed (or located) at a first end of the first pad area PA1. The input pads IP may be repeatedly arranged along the first direction DR1. The input pads IP may receive input signals.

The output pads OP may be disposed (or located) in the first pad area PA1. The output pads OP may be disposed (or located) at a second end of the first pad area PA1 opposite to the first end. The first end may be closer to the second pad area PA2 than the second end. The output pads OP may be repeatedly arranged along the first direction DR1. The output pads OP may output an output signal (e.g., a driving signal) to the pixels PX based on the input signal.

The first test pads TP1-P may be disposed (or located) in the first pad area PA1. In an embodiment, the first test pads TP1-P may be disposed (or located) at the second end of the first pad area PA1. For example, the first test pads TP1-P may be disposed (or located) at the left and right ends of the second end of the first pad area PA1, respectively.

The signal pads SP may be disposed (or located) in the second pad area PA2. The signal pads SP may be repeatedly arranged along the first direction DR1. The signal pads SP may provide the input signal to the input pads IP.

The second-first test pads TP21-P may be disposed (or located) in the second pad area PA2. For example, the second-first test pads TP21-P may be disposed (or located) on the left and right sides of the second pad area PA2, respectively. In addition, the second-first test pads TP21-P may be disposed (or located) between the signal pads SP and the second-second test pads TP22-P in the plan view.

The second-second test pads TP22-P may be disposed (or located) in the second pad area PA2. For example, the second-second test pads TP22-P may be disposed (or located) at the left and right ends of the second pad area PA2, respectively.

The display panel DP may further include first, second, third, and fourth test lines TL1, TL2, TL3, and TL4. Each of the respective first, second, third, and fourth test lines TL1, TL2, TL3, and TL4 may electrically connect one of the first test pads TP1-P to one of the second-first test pads TP21-P, as illustrated in FIG. 6. In an embodiment, the first, second, third, and fourth test lines TL1, TL2, TL3, and TL4 may be connected one-to-one to the second-first test pads TP21-P, and the second and third test lines TL2 and TL3 may be connected to a single first test pad TP1-P among the first test pads TP1-P. In other words, the second and third test lines TL2 and TL3 may be electrically connected to each other.

The driving integrated circuit DIC may include a first base substrate BS1, a plurality of first test bumps TB1-C disposed (or located) on the first base substrate BS1, a plurality of output bumps OBP disposed (or located) on the first base substrate BS1, and a plurality of input bumps IBP disposed (or located) on the first base substrate BS1.

The first test bumps TB1-C may be connected one-to-one to the first test pads TP1-P. The output bumps OBP may be connected one-to-one to the output pads OP. In addition, the input bumps IBP may be connected one-to-one to the input pads IP. Accordingly, the driving integrated circuit DIC may be bonded to the first pad area PA1. In an embodiment, the driving integrated circuit DIC may be electrically connected to the display panel DP.

The first circuit board CB1 may include a second base substrate BS2, a plurality of second-first test bumps TB21-C disposed (or located) on the second base substrate BS2, a plurality of second-second test bumps TB22-C disposed (or located) on the second base substrate BS2, a plurality of bump electrodes BP disposed (or located) on the second base substrate BS2, and a first connector CNT1 disposed (or located) on the second base substrate BS2.

The second-first test bumps TB21-C may be connected one-to-one with the second-first test pads TP21-P. The second-second test bumps TB22-C may be connected one-to-one with the second-second test pads TP22-P. In addition, the signal pads SP may be connected one-to-one with the bump electrodes BP. Accordingly, the first circuit board CB1 may be bonded to the second pad area PA2. In an embodiment, the first circuit board CB1 may be electrically connected to the display panel DP.

The second circuit board CB2 may be bonded to one end of the first circuit board CB1. In some embodiments, the second circuit board CB2 may be a flexible printed circuit board or a printed circuit board. In an embodiment, the second circuit board CB2 may be a flexible printed circuit board.

The second circuit board CB2 may include a third base substrate BS3 and second and third connectors CNT2 and CNT3 disposed (or located) on the third base substrate BS3.

As shown in FIG. 8, the second circuit board CB2 may be bonded to the first circuit board CB1 through the second connector CNT2 of the second circuit board CB2 and the first connector CNT1 of the first circuit board CB1. Accordingly, in an embodiment, the second circuit board CB2 may be electrically connected to the first circuit board CB1.

The first circuit board CB1 may further include first-first, first-second, first-third, and first-fourth test transmission lines TTL11, TTL12, TTL13, and TTL14, and second-first, second-second, second-third, and second-fourth test transmission lines TTL21, TTL22, TTL23, and TTL24 disposed (or located) on the second base substrate BS2.

In some embodiments, each of the first-first, first-second, first-third, and first-fourth test transmission lines TTL11, TTL12, TTL13, and TTL14 may electrically connect one of the second-first test pads TP21-P and the first and second connectors CNT1 and CNT2, respectively. In other words, the first-first, first-second, first-third, and first-fourth test transmission lines TTL11, TTL12, TTL13, and TTL14 may each, respectively, connect one of the second-first test pads TP21-P to both the first and second connectors CNT1 and CNT2. In an embodiment, as also illustrated in FIG. 7, the first-first test transmission line TTL11 may be connected to one of the second-first test pads TP21-P. The first-second test transmission line TTL12 may be connected to another one of the second-first test pads TP21-P. The first-third test transmission line TTL13 may be connected to another one of the second-first test pads TP21-P. The first-fourth test transmission line TTL14 may be connected to another one of the second-first test pads TP21-P.

In some embodiments, each of the second-first, second-second, second-third, and second-fourth test transmission lines TTL21, TTL22, TTL23, and TTL24 may electrically connect one of the second-second test pads TP22-P and the first and second connectors CNT1 and CNT2, respectively. In other words, the second-first, second-second, second-third, and second-fourth test transmission lines TTL21, TTL22, TTL23, and TTL24 may each, respectively, connect one of the second-second test pads TP22-P to both the first and second connectors CNT1 and CNT2. In an embodiment, as also illustrated in FIG. 7, the second-first test transmission line TTL21 may be connected to one of the second-second test pads TP22-P. The second-second test transmission line TTL22 may be connected to another one of the second-second test pads TP22-P. The second-third test transmission line TTL23 may be connected to the same one of the second-second test pads TP22-P, as to which the second-second test transmission line TTL22 is connected. And, the second-fourth test transmission line TTL24 may be connected to another one of the second-second test pads TP22-P.

In some embodiments, first-first, first-second, first-third, and first-fourth test transmission lines TTL11, TTL12, TTL13, and TTL14 may be connected one-to-one to the second-first test pads TP21-P, and the second-second and second-third test transmission lines TTL22 and TTL23 may be connected to a single (one) second-second test pad TP22-P among the second-second test pads TP22-P. In an embodiment, the second-second and second-third test transmission lines TTL22 and TTL23 may be electrically connected to each other.

The second circuit board CB2 can be connected to an inspection device through the third connector CNT3. After bonding the first circuit board CB1 to the display panel DP, and bonding the second circuit CB2 to the first circuit board CB1, the inspection device may inspect the first circuit board CB1 for defects. After the inspection of the first circuit board CB1 is completed, the third connector CNT3 may be separated from the inspection device.

In an embodiment, the second circuit board CB2 may further include a first test terminal group TG1, a second test terminal group TG2, first-first, first-second, first-third, and first-fourth test connection lines TCL11, TCL12, TCL13, and TCL14, and second-first, second-second, second-third, and second-fourth test connection lines TCL21, TCL22, TCL23, and TCL24 disposed (or located) on the third base substrate BS3.

The first test terminal group TG1 may include first-first, first-second, first-third, and first-fourth test terminals TT11, TT12, TT13, and TT14, and the second test terminal group TG2 may include second-first, second-second, second-third, and second-fourth test terminals TT21, TT22, TT23, and TT24. In an embodiment, the second circuit board CB2 may include two first test terminal groups TG1, and two second test terminal groups TG2. However, embodiments of the present disclosure are not necessarily limited thereto.

The first-first test connection line TCL11 may connect the first-first test terminal TT11 to the first and second connectors CNT1 and CNT2. In addition, the first-first test connection line TCL11 may be connected to the first-first test transmission line TTL11 through the first and second connectors CNT1 and CNT2. Accordingly, the first-first test connection line TCL11 may electrically connect the first-first terminal TT11 to one of the second-first test pads TP21-P.

The first-second test connection line TCL12 may connect the first-second test terminal TT12 to the first and second connectors CNT1 and CNT2. In addition, the first-second test connection line TCL12 may be connected to the first-second test transmission line TTL12 through the first and second connectors CNT1 and CNT2. Accordingly, the first-second test connection line TCL12 may electrically connect the first-second test terminal TT12 to another one of the second-first test pads TP21-P.

The first-third test connection line TCL13 may connect the first-third test terminal TT13 to the first and second connectors CNT1 and CNT2. In addition, the first-third test connection line TCL13 may be connected to the first-third test transmission line TTL13 through the first and second connectors CNT1 and CNT2. Accordingly, the first-third test connection line TCL13 may electrically connect the first-third test terminal TT13 to another one of the second-first test pads TP21-P.

The first-fourth test connection line TCL14 may connect the first-fourth test terminal TT14 to the first and second connectors CNT1 and CNT2. In addition, the first-fourth test connection line TCL14 may be connected to the first-fourth test transmission line TTL14 through the first and second connectors CNT1 and CNT2. Accordingly, the first-fourth test connection line TCL14 may electrically connect the first-fourth test terminal TT14 to the remaining one of the second-first test pads TP21-P.

In an embodiment, a first current may be supplied to the first-first test terminal TT11, a ground voltage may be applied to the first-second test terminal TT12, a first voltage may be applied to the first-third test terminal TT13, and a second voltage different from the first voltage may be applied to the first-fourth test terminal TT14. A first contact resistance (i.e., the first contact resistance between the first test pads TP1-P and the first test bumps TB1-C) between the display panel DP and the driving integrated circuit DIC may be calculated through the first current, the first voltage, and the second voltage. The first contact resistance may be calculated through Equation 1 below.

$${R}_{1} = ( {V}_{2} - {V}_{1} ) / {I}_{1} \qquad < Equation 1 >$$

Here, R₁ is the first contact resistance, V₂ is the second voltage, V₁ is the first voltage, and I₁ is the first current.

In an embodiment, if it is evaluated that the first test pads TP1-P and the first test bumps TB1-C are connected properly, a connection between the input pads IP and the input bumps IBP, and a connection between the output pads OP and the output bumps OBP may also be deemed proper. As a result, by calculating the first contact resistance, it may be evaluated if the display panel DP and the driving integrated circuit DIC are properly bonded.

The second-first test connection line TCL21 may connect the second-first test terminal TT21 to the first and second connectors CNT1 and CNT2. In addition, the second-first test connection line TCL21 may be connected to the second-first test transmission line TTL21 through the first and second connectors CNT1 and CNT2. Accordingly, the second-first test connection line TCL21 may electrically connect the second-first terminal TT21 to one of the second-second test pads TP22-P.

The second-second test connection line TCL22 may connect the second-second test terminal TT22 to the first and second connectors CNT1 and CNT2. In addition, the second-second test connection line TCL22 may be connected to the second-second test transmission line TTL22 through the first and second connectors CNT1 and CNT2. Accordingly, the second-second test connection line TCL22 may electrically connect the second-second test terminal TT22 to another one of the second-second test pads TP22-P.

The second-third test connection line TCL23 may connect the second-third test terminal TT23 to the first and second connectors CNT1 and CNT2. In addition, the second-third test connection line TCL23 may be connected to the second-third test transmission line TTL23 through the first and second connectors CNT1 and CNT2. Accordingly, the second-third test connection line TCL23 may electrically connect the second-third test terminal TT23 to another one of the second-second test pads TP22-P. In an embodiment, the second-second test connection line TCL22 and the second-second test connection line TCL23 may be connected to a single (same) second-second test pad TP22-P, as illustrated in FIG. 7.

The second-fourth test connection line TCL24 may connect the second-fourth test terminal TT24 to the first and second connectors CNT1 and CNT2. In addition, the second-fourth test connection line TCL24 may be connected to the second-fourth test transmission line TTL24 through the first and second connectors CNT1 and CNT2. Accordingly, the second-fourth test connection line TCL24 may electrically connect the second-fourth test terminal TT24 to the remaining one of the second-second test pads TP22-P.

In an embodiment, a second current may be supplied to the second-first test terminal TT21, a ground voltage may be applied to the second-second test terminal TT22, a third voltage may be applied to the second-third test terminal TT23, and a fourth voltage different from the third voltage may be applied to the second-fourth test terminal TT24. A second contact resistance (i.e., the second contact resistance between the second-first and second-second test pads TP21-P and TP22-P and the second-first and second-second test bumps TB21-C and TB21-C) between the display panel DP and the first circuit board CB1 may be calculated through the second current, the third voltage, and the fourth voltage. The second contact resistance may be calculated through Equation 2 below.

$${R}_{2} = ( {V}_{4} - {V}_{3} ) / {I}_{2} \qquad < Equation 2 >$$

Here, R₂ is the second contact resistance, V₃ is the third voltage, V₄ is the fourth voltage, and I₂ is the second current.

In an embodiment, if it is evaluated that the second-first and second-second test pads TP21-P and TP22-P and the second-first and second-second test bumps TB21-C and TB21-C are connected properly, the connection between the signal pads SP and the bump electrodes BP may also be deemed proper. As a result, it can be inspected whether the display panel DP and the first circuit board CB1 are properly bonded using the second contact resistance.

In a comparative example, in order to measure the contact resistance between a display panel and a driving integrated circuit and the contact resistance between the display panel and a first circuit board, a first test terminal group and a second test terminal group were disposed (or located) on the first circuit board. In this case, an area of the first circuit board for an arrangement of the first and second test terminal groups may be relatively large, and the degree of design freedom may be reduced.

In the display module DM, according to embodiments of the present disclosure, the second circuit board CB2 bonded to the first circuit board CB1 may include the first test terminal group TG1 and the second test terminal group TG2 to measure the contact resistance between the display panel DP and the driving integrated circuit DIC, and the contact resistance between the display panel DP and the first circuit board CB1. Accordingly, the area of the first circuit board CB1 may be reduced, and the degree of design freedom may be increased.

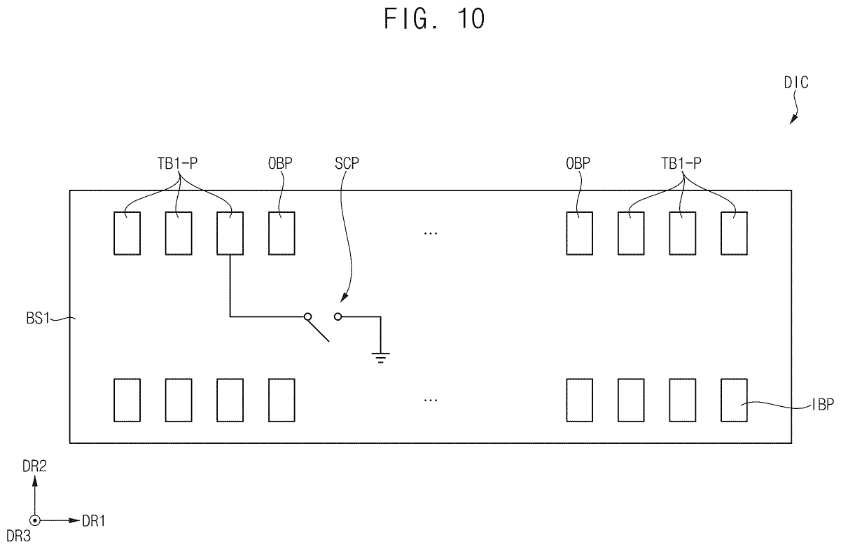

FIG. 10 is a plan view showing a driving integrated circuit included in the display module of FIG. 7.

Referring to FIG. 10, in an embodiment, the driving integrated circuit DIC may further include a switching circuit SCP disposed (or located) on the first base substrate BS1, electrically connected to at least one of the first test pads TP1-P of FIGS. 6 and 7 via TB1-P. The switching circuit may include a switching element configured to selectively receive a ground voltage.

In some embodiments, before removing the second circuit board CB2 from the first circuit board CB1 (i.e., when measuring the contact resistance between the driving integrated circuit DIC and the display panel DP and the contact resistance between the first circuit board CB1 and the display panel DP), the switching element may be turned off. In this case, the switching element may not receive the ground voltage. Alternatively, after removing the second circuit board CB2 from the first circuit board CB1, the switching element may be turned on. In this case, the switching element may transmit the ground voltage to the first test pads TP1-P of FIGS. 6 and 7. Accordingly, defects due to inflow of electro-static discharge (ESD) may be minimized or reduced.

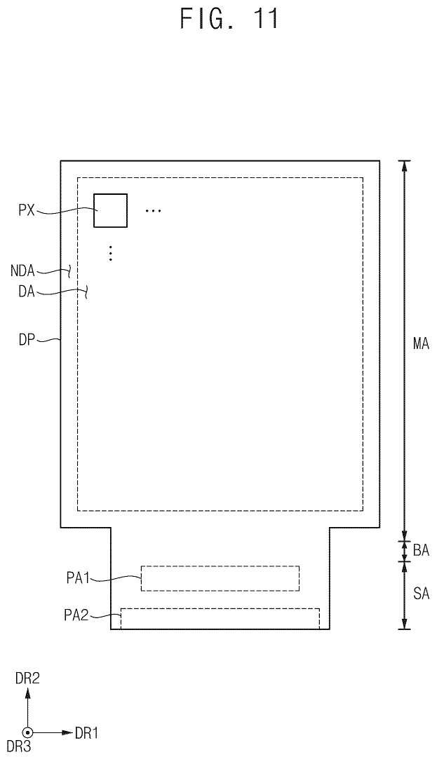

FIGS. 11, 12, and 13 are plan views for explaining a method for manufacturing a display device comprising a display panel, according to embodiments of the present disclosure. Hereinafter, descriptions that overlap with those described with reference to FIGS. 1 to 10 will be omitted or simplified.

Referring to FIG. 11, the display panel DP may be formed. Configurations of the display panel DP may be substantially the same as those described with reference to FIGS. 1 to 7. In an embodiment, as shown in FIG. 2, the display panel DP may include the substrate 110, the pixel circuit layer 120, the light-emitting element layer 130, and the encapsulation layer 140. In addition, as shown in FIG. 6, the display panel DP may include the input pads IP, the output pads OP, the first test pads TP1-P, the second-first test pads TP21-P, the second-second test pads TP22-P, and the signal pads SP.

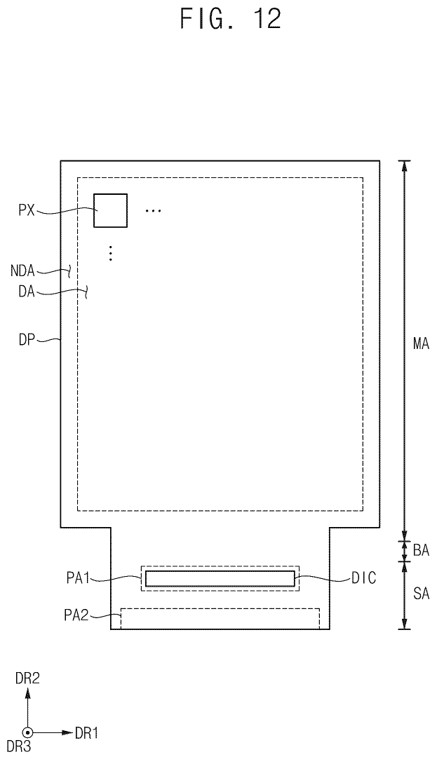

Referring to FIG. 12, the driving integrated circuit DIC may be bonded to the first pad area PA1 on the display panel DP. For example, the driving integrated circuit DIC may be bonded to the input pads IP, the output pads OP, and the first test pads TP1-P of FIG. 6 disposed (or located) in the first pad area PA1. In some embodiments, the driving integrated circuit DIC may be bonded through a thermal compression method.

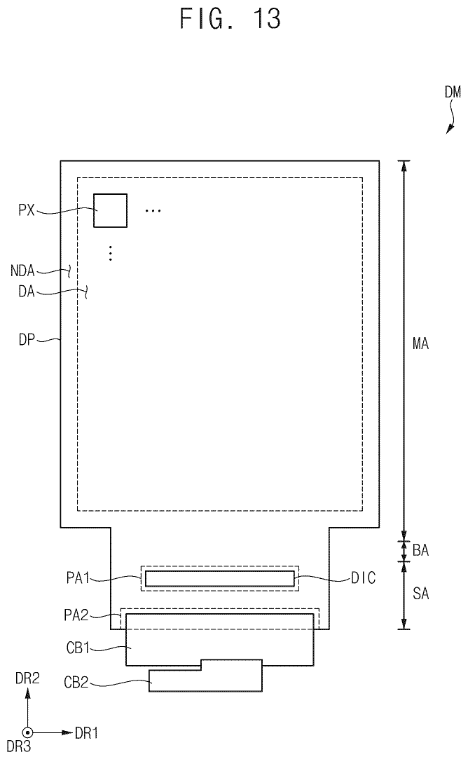

Referring to FIG. 13, the first circuit board CB1 to which the second circuit board CB2 is attached may be bonded to the second pad area PA2 on the display panel DP. The second circuit board CB2 may include the first test terminal group TG1 and the second test terminal group TG2 of FIGS. 7 and 9.

In an embodiment, the first circuit board CB1 to which the second circuit board CB2 is attached may be bonded to the second-first test pads TP21-P, the second-second test pads TP22-P, and the signal pads SP of FIG. 6 disposed (or located) in the second pad area PA2. In some embodiments, the first circuit board CB1 may be bonded using a thermal compression method. Accordingly, the display module DM may be manufactured.

After the display module DM is manufactured, the first contact resistance between the display panel DP and the driving integrated circuit DIC and the second contact resistance between the display panel DP and the first circuit board CB1 may be measured. The method of measuring the first and second contact resistances is as described above.

The second circuit board CB2 may be connected to an inspection device through the third connector CNT3 of FIGS. 7 and 9. After bonding the first circuit board CB1 to the display panel DP, while the second circuit CB2 is bonded to the first circuit board CB1, the inspection device may inspect the first circuit board CB1 for defects. After the inspection of the first circuit board CB1 is completed, the third connector CNT3 may be separated from the inspection device.

Next, the second circuit board CB2 may be removed from the first circuit board CB1. Accordingly, the display device DD shown in FIGS. 1 and 2 may be manufactured.

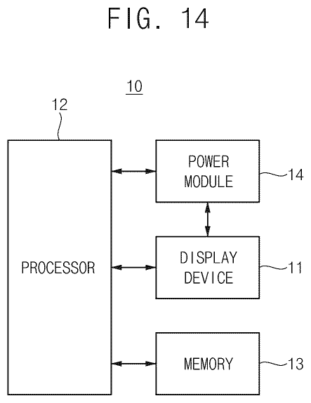

FIG. 14 is a block diagram showing an electronic device according to embodiments of the present disclosure.

Referring to FIG. 14, an electronic device 10 may include a display device 11, a processor 12, a memory 13, and a power module 14.

The display device 11, according to embodiments herein, may be used in various electronic devices 10. The electronic device 10 may include the display device 11 described above, and may further include modules or devices with additional functions other than the display device 11. The display device 11 may correspond to the display device DD of FIG. 1.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display device 11. When the processor 12 executes the application stored in the memory 13, an image data signal and/or an input control signal may be transmitted to the display device 11, and the display device 11 may process the received signal and output image information through a display screen. In other words, the processor 12 may control the display device 11.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device 11, according to the above-described embodiments. In addition, some of the individual modules functionally included in one module may be included in the display device 11, and other modules may be provided separately from the display device 11. For example, the processor 12, the memory 13, and the power module 14 may be provided in the form of other devices within the electronic device 10 other than the display device 11.

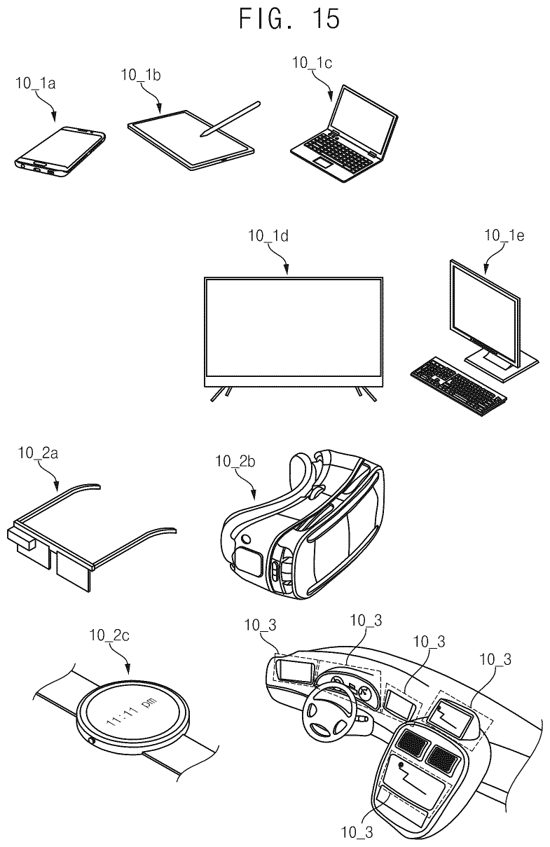

FIG. 15 are schematic diagrams showing an electronic device according to various embodiments.

Referring to FIG. 15, various electronic devices 10 are illustrated. Electronic devices 10 may comprise display modules, according to the embodiments disclosed herein (e.g., in FIG. 1). The electronic devices 10 comprising display modules may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, a smart watch 10_2c, and automotive electronic devices 10_3 including display modules, such as a dashboard of a car, a center fascia, a Center Information Display (CID) disposed on a dashboard, and a room mirror display, or the like.

The present disclosure can be applied to various display devices which can be equipped with a display device and a display module. For example, the present disclosure can be applied to high-resolution smartphones, mobile phones, smart pads, smart watches, tablet PCs, vehicle navigation systems, televisions, computer monitors, laptops, and the like.

Although embodiments of the present disclosure have been described with reference to the accompanying drawings, the disclosure is not limited to these embodiments. Those skilled in the art will recognize that many modifications are possible in the disclosed embodiments without materially departing from the novel teachings and advantages of the present inventive concept. Accordingly, all such modifications are intended to be included within the scope of the present inventive concept as defined in the claims. Therefore, the described embodiments should be regarded as illustrative rather than restrictive in all respects. Moreover, modifications to the disclosed embodiments, as well as other embodiments, are intended to be included within the scope of the appended claims.

What is claimed is:

1. A display module comprising:
a display panel comprising:
a plurality of pixels located in a display area, a plurality of first test pads located in a first pad area, a plurality of second-first test pads located in a second pad area spaced apart from the first pad area and electrically connected to the first test pads, and a plurality of second-second test pads located in the second pad area;
a driving integrated circuit bonded to the first test pads, the driving integrated circuit configured to provide driving signals to the pixels;
a first circuit board bonded to the second-first test pads and the second-second test pads; and
a second circuit board bonded to one end of the first circuit board, the second circuit board including a first test terminal group electrically connected to the second-first test pads and a second test terminal group electrically connected to the second-second test pads.

2. The display module of claim 1, wherein
the first test terminal group includes first-first, first-second, first-third, and first-fourth test terminals and the second test terminal group includes second-first, second-second, second-third, and second-fourth test terminals, wherein:
the first-first and second-first test terminals are configured to receive a current flow,
the first-second and second-second test terminals are configured to receive a ground voltage,
the first-third and second-third test terminals are configured to receive a first voltage, and
the first-fourth and the second-fourth test terminals are configured to receive a second voltage different from the first voltage.

3. The display module of claim 2, wherein the second circuit board comprises:
a first-first test connection line electrically connected to the first-first test terminal and to one of the second-first test pads;
a first-second test connection line electrically connected to the first-second test terminal and to another one of the second-first test pads;
a first-third test connection line electrically connected to the first-third test terminal and to another one of the second-first test pads; and
a first-fourth test connection line electrically connected to the first-fourth test terminal and to remaining one of the second-first test pads.

4. The display module of claim 3, wherein the second circuit board further comprises:
a second-first test connection line electrically connected to the second-first test terminal and to one of the second-second test pads;
a second-second test connection line electrically connected to the second-second test terminal and to another one of the second-second test pads;
a second-third test connection line electrically connected to the second-third test terminal and to another one of the second-second test pads; and
a second-fourth test connection line electrically connected to the second-fourth test terminal and to remaining one of the second-second test pads.

5. The display module of claim 1, wherein:
a first connector is disposed on the first circuit board,
a second connector is disposed on the second circuit board, and
the first circuit board and the second circuit board are bonded through the first connector and the second connector.

6. The display module of claim 5, wherein the display panel further comprises first, second, third, and fourth test lines each, respectively, electrically connected to one of the first test pads to one of the second-first test pads, and
the first circuit board includes:
first-first, first-second, first-third, and first-fourth test transmission lines each, respectively, electrically connected to one of the second-first test pads and to the first and second connectors; and
second-first, second-second, second-third, and second-fourth test transmission lines each, respectively, electrically connected to one of the second-second test pads and to the first and second connectors.

7. The display module of claim 6, wherein:
the first, second, third, and fourth test lines are connected one-to-one to the second-first test pads, and
the second and third test lines are connected to a single first test pad among the first test pads.

8. The display module of claim 6, wherein:
the first-first, first-second, first-third, and first-fourth test transmission lines are connected one-to-one to the second-first test pads, and
the second-second and second-third test transmission lines are connected to a single second-second test pad among the second-second test pads.

9. The display module of claim 1, wherein the driving integrated circuit comprises:
a switching circuit electrically connected to at least some of the first test pads, the switching circuit including a switching element configured to selectively receive a ground voltage.

10. The display module of claim 1, wherein the display panel further comprises:
a plurality of input pads located at a first end of the first pad area; and
a plurality of output pads located at a second end of the first pad area opposite to the first end, the output pads configured to output the driving signals to the pixels, and
the first test pads located at the second end of the first pad area.

11. The display module of claim 10, wherein the driving integrated circuit comprises:
a plurality of input bumps connected one-to-one to the input pads;
a plurality of test bumps connected one-to-one to the first test pads; and
a plurality of output bumps connected one-to-one to the output pads.

12. The display module of claim 1, wherein the first circuit board comprises:
a plurality of second-first test bumps connected one-to-one to the second-first test pads; and
a plurality of second-second test bumps connected one-to-one to the second-second test pads.

13. A method for manufacturing a display device, the method comprising:
forming a plurality of pixels in a display area of a display panel; forming a plurality of first test pads in a first pad area of the display panel; forming a plurality of second-first test pads in a second pad area of the display panel spaced apart from the first pad area;
connecting electrically the first test pads to the second-first test pads; and forming a plurality of second-second test pads in the second pad area of the display panel;
bonding a driving integrated circuit to the first test pads, the driving integrating circuit providing driving signals to the pixels;
bonding a first circuit board to the second-first test pads and the second-second test pads; and
bonding a second circuit board to one end of the first circuit board and disposing a first test terminal group and a second terminal group on the second circuit board, the first test terminal group connecting electrically to the second-first test pads and the second test terminal group connecting electrically to the second-second test pads; and
removing the second circuit board from the first circuit board.

14. The method of claim 13, wherein
the first test terminal group includes first-first, first-second, first-third, and first-fourth test terminals and the second test terminal group includes second-first, second-second, second-third, and second-fourth test terminals, and
before the removing the second circuit board,
applying a current to the first-first and second-first test terminals,
applying a ground voltage to the first-second and second-second test terminals,
applying a first voltage to the first-third and second-third test terminals, and
applying a second voltage different from the first voltage to the first-fourth and the second-fourth test terminals.

15. The method of claim 14, wherein the bonding the second circuit board comprises:
connecting electrically the first-first test terminal to one of the second-first test pads through a first-first test connection line;
connecting electrically the first-second test terminal and another one of the second-first test pads through a first-second test connection line;
connecting electrically the first-third test terminal and another one of the second-first test pads through a first-third test connection line; and
connecting electrically the first-fourth test terminal and remaining one of the second-first test pads through a first-fourth test connection line.

16. The method of claim 15, wherein the bonding the second circuit board further comprises:
connecting electrically the second-first test terminal and one of the second-second test pads through a second-first test connection line;
connecting electrically the second-second test terminal and another one of the second-second test pads through a second-second test connection line;
connecting electrically the second-third test terminal and another one of the second-second test pads through a second-third test connection line; and
connecting electrically the second-fourth test terminal and remaining one of the second-second test pads through a second-fourth test connection line.

17. The method of claim 13, wherein the method further includes the steps of:
disposing a first connector on the first circuit board,
disposing a second connector on the second circuit board, and
bonding the first circuit board and the second circuit board through the first connector and the second connector,
connecting electrically one of the first test pads to one of the second-first test pads through first, second, third, and fourth test lines, respectively, and
bonding the first circuit board comprising:
connecting electrically one of the second-first test pads to the first and second connectors through first-first, first-second, first-third, and first-fourth test transmission lines, respectively; and
connecting electrically one of the second-second test pads to the first and second connectors through second-first, second-second, second-third, and second-fourth test transmission lines, respectively.

18. The method of claim 17, wherein the method further includes the steps of:
connecting the first, second, third, and fourth test lines one-to-one to the second-first test pads,
connecting the second and third test lines to a single first test pad among the first test pads,
connecting the first-first, first-second, first-third, and first-fourth test transmission lines one-to-one to the second-first test pads, and
connecting the second-second and second-third test transmission lines to a single second-second test pad among the second-second test pads.

19. The method of claim 13, wherein the manufacturing the display device comprises:
forming the display panel;
bonding the driving integrated circuit to the first test pads;
bonding the first circuit board to which the second circuit board is attached to the second-first test pads and the second-second test pads; and
connecting the second circuit board to an inspection device to inspect the first circuit board.

20. An electronic device comprising:
a display device manufactured according to claim 13;
a processor configured to control the display device by providing input image data and control signal to the display device;
a power module configured to provide power to the display device; and
a memory.
